(19) United States
(12) Patent Application Publication
(10) Pub. No.: US 2016/0122503 A1
(43) Pub. Date: May 5, 2016

(54) RESIN COMPOSITION FOR THERMALLY CONDUCTIVE SHEET, BASE MATERIAL-ATTACHED RESIN LAYER, THERMALLY CONDUCTIVE SHEET, AND SEMICONDUCTOR DEVICE

(71) Applicant: SUMITOMO BAKELITE CO., LTD., Tokyo (JP)

(72) Inventors: Shunsuke Mochizuki, Tokyo (JP); Kazuya Kitagawa, Tokyo (JP); Yoji Shirato, Tokyo (JP); Keita Nagahashi, Tokyo (JP); Mika Tsuda, Tokyo (JP); Kazuya Hirasawa, Kariya-shi (JP); Motomi Kurokawa, Aichi-ken (JP)

(73) Assignee: SUMITOMO BAKELITE CO., LTD., Tokyo (JP)

(21) Appl. No.: 14/931,966

(22) Filed: Nov. 4, 2015

(30) Foreign Application Priority Data
Nov. 5, 2014 (JP) 2014-225477

(51) Int. Cl. C08K 3/38; H01L 23/367; H01L 23/31; C09K 5/08

(52) U.S. Cl. CPC C08K 3/38; C09K 5/08; H01L 23/3672; H01L 23/3135; C08K 2003/385

(57) ABSTRACT

A resin composition for a thermally conductive sheet includes a thermosetting resin and a filler dispersed in the thermosetting resin. The filler includes secondary agglomerated particles satisfying the following conditions: a void is formed in the central portion; a communicating pore which begins from the void and communicates with the outer surface of the secondary agglomerated particle is formed; and the ratio of the average pore diameter of the communicating pores to the average void diameter of the voids is equal to or more than 0.05 and equal to or less than 1.0.

The present application claims priority on the basis of Japanese Patent Application No. 2014-225477 filed on Nov. 5, 2014, and the content thereof is incorporated herein by reference.

### BACKGROUND

1. Technical Field

The present invention relates to a resin composition for a thermally conductive sheet, a base material-attached resin layer, a thermally conductive sheet, and a semiconductor device.

2. Related Art

An inverter device or a power semiconductor device constituted by mounting electronic components such as semiconductor chips such as an insulated gate bipolar transistor (IGBT) and a diode, a resistor, and a capacitor on a substrate has been known thus far.

This power control device is applied to a variety of devices depending on breakdown voltage or a current capacity thereof. Particularly, the use of this power control device in a variety of electrical machines has been expanding every year from the viewpoint of the recent environmental problem and implementation of energy saving.

Particularly, for an on-board power control device, together with size reduction and space saving, it has been required to install the power control device in an engine room. The inside of an engine room is a severe environment in which the temperature is high and the temperature significantly changes, and thus there is need for an insulating member having superior thermal radiation properties.

For example, Japanese Unexamined Patent Publication No. 2011-216619 discloses a semiconductor device in which a semiconductor chip is mounted on a supportive body such as a lead frame, and the supportive body and a thermal radiator board connected to a heat sink are adhered together using an insulating resin layer.

### SUMMARY

However, the above-described semiconductor device is not yet capable of sufficiently satisfying thermal radiation properties. Therefore, there are cases in which it is difficult to transfer heat from an electronic component to the outside, and, in such cases, the performance of the semiconductor device degrades.

In one embodiment, there is provided a resin composition for a thermally conductive sheet including: a thermosetting resin; and a filler dispersed in the thermosetting resin, in which the filler includes secondary agglomerated particles satisfying the following conditions (a), (b), and (c).

(a) A void is formed in a central portion.

(b) A communicating pore which begins from the void and communicates with an outer surface of the secondary agglomerated particle is formed.

(c) A ratio of an average pore diameter of the communicating pores to an average void diameter of the voids is equal to or more than 0.05 and equal to or less than 1.0.

In addition, in another embodiment, there is provided a base material-attached resin layer including: a resin layer made of the resin composition for a thermally conductive sheet; and a base material provided on at least one surface of the resin layer.

In addition, in another embodiment, there is provided a thermally conductive sheet formed of the resin composition for a thermally conductive sheet.

In addition, in another embodiment, there is provided a semiconductor device including: a metal plate; a semiconductor chip provided on a first face side of the metal plate; a thermally conductive material joined to a second face of the metal plate opposite to the first face; and an encapsulating resin which encapsulates the semiconductor chip and the metal plate, in which the thermally conductive material is formed of the thermally conductive sheet.

According to the present invention, it is possible to provide a resin composition for a thermally conductive sheet capable of realizing a highly durable semiconductor device and a highly durable semiconductor device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic sectional view of a secondary agglomerated particle according to an embodiment of the present invention.

FIG. 2 is a schematic sectional view of a thermally conductive sheet according to an embodiment of the present invention.

FIG. 3 is a sectional view of a semiconductor device according to an embodiment of the present invention.

FIG. 4 is a sectional view of a semiconductor device according to an embodiment of the present invention.

FIG. 5 is a view illustrating an electron micrograph of filler used in Example 1.

FIG. 6 is a view illustrating an electron micrograph of filler used in Comparative Example 1.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, embodiments of the present invention will be described on the basis of the accompanying drawings. Meanwhile, in all the drawings, the same components will be given the same reference numeral and detailed description thereof will not be repeated in order to avoid duplicate description. In addition, the drawings are schematic views and do not always reflect actual dimensional ratios. Furthermore, “to” used to express a numerical range means equal to or more than and equal to or less than unless particularly otherwise described.

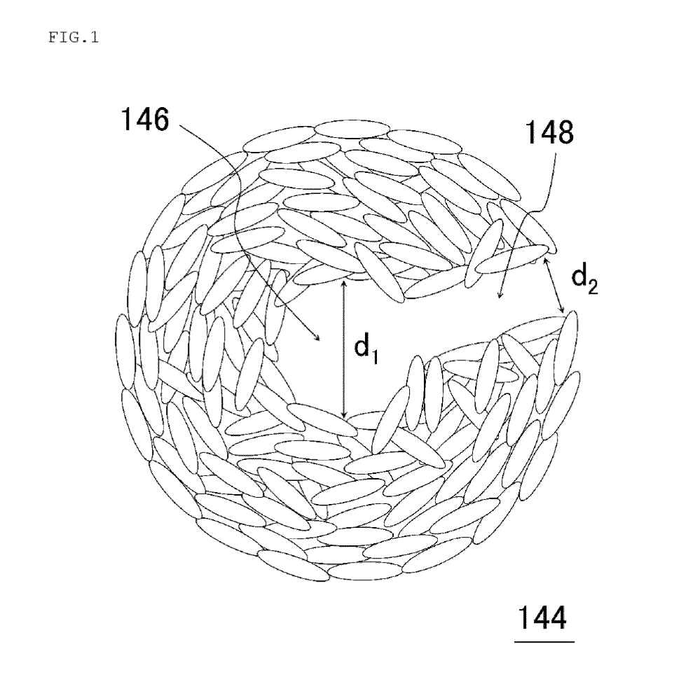

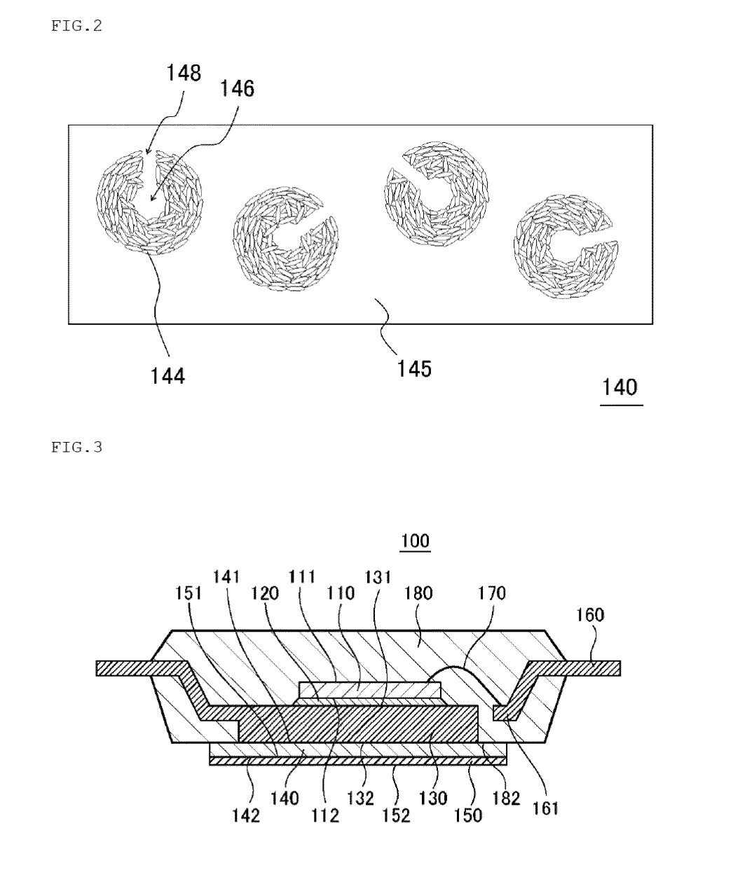

In the beginning, a resin composition for a thermally conductive sheet and a thermally conductive sheet according to the present embodiment will be described. FIG. 1 is a schematic sectional view of a secondary agglomerated particle 144 according to an embodiment of the present invention. FIG. 2 is a schematic sectional view of a thermally conductive sheet 140 according to an embodiment of the present invention.

Hereinafter, in order to simplify description, in some cases, it is assumed that the positional relationship (vertical structure relationship or the like) between individual components in a semiconductor device 100 coincides with the relationships illustrated in the drawings. However, the positional relationship in the description has no relationship with the positional relationship while the semiconductor device 100 is used or manufactured.

The resin composition for a thermally conductive sheet and the thermally conductive sheet 140 according to the present embodiment include a thermosetting resin (A) 145 and a filler (B) dispersed in the thermosetting resin (A) 145.

The filler (B) includes secondary agglomerated particles 144 satisfying the following conditions (a), (b), and (c).

(a) A void 146 is formed in the central portion.

(b) A communicating pore 148 which begins from the void 146 and communicates with the outer surface of the secondary agglomerated particle 144 is formed.

(c) The ratio of the average pore diameter of the communicating pores 148 to the average void diameter of the voids 146 is equal to or more than 0.05 and equal to or less than 1.0.

Meanwhile, in the present embodiment, the thermally conductive sheet 140 refers to a sheet in a B stage state. In addition, the thermally conductive sheet 140 which is applied to the semiconductor device and is cured will be referred to as “thermally conductive material”.

The thermally conductive sheet is provided, for example, in a joint interface in the semiconductor device at which high thermal conductivity is required and accelerates thermal conduction from a heat-generating body to a thermal radiation body. Then, malfunction caused by fluctuation in characteristics in a semiconductor chip or the like is suppressed, and the stability of the semiconductor device is improved.

Examples of the semiconductor device to which the thermally conductive sheet 140 according to the present embodiment is applied include a structure in which a semiconductor chip is provided on a heat sink (metal plate) and the thermally conductive material 140 is provided on a surface of the heat sink opposite to the surface to which the semiconductor chip is joined.

In addition, additional examples of a semiconductor package to which the thermally conductive sheet according to the present embodiment is applied include a semiconductor package provided with the thermally conductive material 140, a semiconductor chip joined to one surface of the thermally conductive material 140, a metal member joined to the surface of the thermally conductive material opposite to the surface to which the semiconductor chip is joined, and an encapsulating resin which encapsulates the thermally conductive material, the semiconductor chip, and the metal member.

The use of the thermally conductive sheet 140 according to the present embodiment can realize a highly durable semiconductor device. The reasons for this are not clear but are considered to be as below.

According to studies of the present inventors, it has been clarified that, when a semiconductor device in which a thermally conductive sheet of the related art is used is placed in an environment with a violent temperature change such as in an engine room of a car for a long period of time, a decrease in the degree of thermal conductivity of the thermally conductive sheet, partial discharge, or the like is caused, and the thermal radiation properties and/or electrical insulating properties of the semiconductor device are degraded. Therefore, the semiconductor device of the related art had poor durability.

On the other hand, a semiconductor device in which the thermally conductive sheet 140 according to the present embodiment is used is excellent in terms of durability even in an environment with a violent temperature change. The reasons for this are considered that the thermally conductive sheet 140 according to the present embodiment has a structure in which voids are not easily generated, and the secondary agglomerated particles 144 are uniformly dispersed in the thermally conductive sheet 140.

First, in the secondary agglomerated particle 144, (a) the void 146 is formed in the central portion, and (b) the communicating pore 148 which begins from the void 146 and communicates with the outer surface of the secondary agglomerated particle 144 is formed. When the secondary agglomerated particle has the above-described structure, a thermosetting resin 145 is capable of intruding into the secondary agglomerated particle 144 through both the outer surface of the secondary agglomerated particle 144 and the inside of the communicating pore 148, and thus the secondary agglomerated particle 144 has an excellent property of being impregnated with the thermosetting resin 145. Therefore, the generation of voids in the thermally conductive sheet 140 and the like can be suppressed, and the degradation of the thermal conductivity of the thermally conductive sheet 140 can be suppressed.

In addition, in the secondary agglomerated particle 144, (c) the ratio of the average pore diameter of the communicating pores 148 to the average void diameter of the voids 146 is equal to or more than 0.05 and equal to or less than 1.0. When the secondary agglomerated particle has the above-described structure, the contact area between the secondary agglomerated particles 144 is increased, and the thermal conductivity of the thermally conductive sheet 140 can be improved.

In addition, the secondary agglomerated particle 144 satisfying the above-described conditions (a), (b), and (c) has a smaller apparent specific gravity and more easily floats in the thermosetting resin than that of the related art. Therefore, the secondary agglomerated particles do not easily sink in the manufacturing stage of the thermally conductive sheet 140 and are uniformly dispersed in the thermally conductive sheet 140. Therefore, even when the semiconductor device is placed in an environment with a violent temperature change for a long period of time, the film thickness of the thermally conductive sheet 140 (thermally conductive material) does not easily change, peeling between the thermally conductive sheet 140 (thermally conductive material) and the semiconductor chip or between the thermally conductive sheet 140 (thermally conductive material) and the substrate can be suppressed, and the degradation of the thermal radiation properties and/or electrical insulating properties of the semiconductor device can be suppressed.

For the above-described reasons, it is inferred that, when the thermally conductive sheet 140 according to the present embodiment is used, a semiconductor device having excellent durability can be obtained.

The thermally conductive sheet 140 is provided, for example, between a heat-generating body such as a semiconductor chip and a substrate such as a lead frame on which the heat-generating body is mounted or an interconnection substrate (interposer) or between the substrate and a thermal radiation body such as a heat sink. In such a case, it is possible to effectively radiate heat generated from the heat-generating body to outside of the semiconductor device. Therefore, it becomes possible to improve the durability of the semiconductor device.

The planar shape of the thermally conductive sheet 140 is not particularly limited, can be appropriately selected depending on the shapes of a thermal radiation member, the heat-generating body, and the like, and can be made to be, for example, rectangular. The film thickness of the thermally conductive sheet is preferably equal to or more than 50 μm and equal to or less than 500 μm. In such a case, it is possible to more effectively transmit heat from the heat-generating body to the thermal radiation member while improving the mechanical strength or the thermal resistance.

The resin composition for a thermally conductive sheet and the thermally conductive sheet 140 according to the present embodiment include the thermosetting resin (A) 145 and the filler (B) dispersed in the thermosetting resin (A) 145.

(Thermosetting Resin (A))

Examples of the thermosetting resin (A) include an epoxy resin, a cyanate resin, a polyimide resin, a benzoxazine resin, an unsaturated polyester resin, a phenol resin, a melamine resin, a silicone resin, a bismaleimide resin, an acrylic resin, and the like. As the thermosetting resin (A), only one resin of the above-described resins may be used, or equal to or more than two resins may be jointly used.

The thermosetting resin (A) is preferably an epoxy resin (A1). The use of the epoxy resin (A1) can increase the glass transition temperature and improve the thermal conductivity of the thermally conductive sheet 140.

Examples of the epoxy resin (A1) include bisphenol-type epoxy resins such as a bisphenol A-type epoxy resin, a bisphenol F-type epoxy resin, a bisphenol E-type epoxy resin, a bisphenol S-type epoxy resin, a bisphenol M-type epoxy resin (4,4′-(1,3-phenylenediisopridiene)bisphenol-type epoxy resin), a bisphenol P-type epoxy resin (4,4′-(1,4-phenylenediisopridiene)bisphenol-type epoxy resin), and a bisphenol Z-type epoxy resin (4,4′-cyclohexydiene bisphenol-type epoxy resin); novolac-type epoxy resins such as a phenol novolac-type epoxy resin, a cresol novolac-type epoxy resin, a trisphenol group methane-type novolac-type epoxy resin, a tetraphenol group ethane-type novolac-type epoxy resin, and a novolac-type epoxy resin having a condensed ring aromatic hydrocarbon structure; biphenyl-type epoxy resins; arylalkylene-type epoxy resins such as a xylylene-type epoxy resin and a biphenylaralkyl-type epoxy resin; naphthalene-type epoxy resins such as a naphthylene ether-type epoxy resin, a naphthol-type epoxy resin, a naphthalenediol-type epoxy resin, a bifunctional or tetrafunctional epoxy-type naphthalene resin, a binaphthyl-type epoxy resin, and a naphthalene aralkyl-type epoxy resin; anthracene-type epoxy resins; phenoxy-type epoxy resins; dicyclopentadiene-type epoxy resins; norbornene-type epoxy resins; adamantane-type epoxy resins; fluorene-type epoxy resins; and the like.

As the epoxy resin (A1), only one resin of the above-described resins may be used, or two or more resins may be jointly used.

Among the epoxy resins (A1), from the viewpoint of further improving the thermal resistance and insulating reliability of the obtained thermally conductive sheet 140, one or two or more resins selected from a group consisting of bisphenol-type epoxy resins, novolac-type epoxy resins, biphenyl-type epoxy resins, arylalkylene-type epoxy resins, naphthalene-type epoxy resins, anthracene-type epoxy resins, and dicyclopentadiene-type epoxy resins are preferred.

The content of the thermosetting resin (A) in the thermally conductive sheet 140 is not particularly limited as long as the content thereof can be appropriately adjusted to be a desired value depending on the purpose, but the content thereof is preferably equal to or more than 1% by mass and equal to or less than 30% by mass, more preferably equal to or more than 3% by mass and equal to or less than 25% by mass, and particularly preferably equal to or more than 5% by mass and equal to or less than 20% by mass, with respect to 100% by mass of the thermally conductive sheet. When the content of the thermosetting resin (A) is equal to or higher than the above-described lower limit value, the handling properties are improved, the formation of the thermally conductive sheet 140 becomes easy, and the strength of the thermally conductive sheet 140 is improved. When the content of the thermosetting resin (A) is equal to or lower than the above-described upper limit value, the linear expansion coefficient or modulus of elasticity of the thermally conductive sheet 140 is further improved or the thermal conductivity of the thermally conductive sheet 140 is further improved.

(Filler (B))

The filler (B) according to the present embodiment includes the secondary agglomerated particles 144 in which (a) the void 146 is formed in the central portion, (b) the communicating pore 148 which begins from the void 146 and communicates with the outer surface is formed, and furthermore, (c) the ratio of the average pore diameter of the communicating pores 148 to the average void diameter of the voids 146 is equal to or more than 0.05 and equal to or less than 1.0. The communicating pore 148 is generally formed to be linear from the void 146 formed in the central portion toward the outer surface of the secondary agglomerated particle 144.

The secondary agglomerated particle 144 is not particularly limited as long as the void 146 and the communicating pore 148 are formed therein; however, from the viewpoint of improving the thermal conductivity of the thermally conductive sheet 140, a secondary agglomerated particle formed by agglomerating scaly boron nitride is preferred.

The shape of the secondary agglomerated particle 144 is not particularly limited and is generally spherical.

The average particle diameter of the secondary agglomerated particles formed by agglomerating scaly boron nitride is, for example, preferably equal to or more than 5 μm and equal to or less than 200 μm and more preferably equal to or more than 50 μm and equal to or less than 150 μm. In such a case, the thermally conductive sheet 140 having superior balance between thermal conductivity and electrical insulating properties can be realized.

The average void diameter of the voids 146 in the secondary agglomerated particles 144 is not particularly limited, but is preferably equal to or more than 2 m and equal to or less than 150 μm, more preferably equal to or more than 10 μm and equal to or less than 100 μm, still more preferably equal to or more than 15 μm and equal to or less than 50 μm, and particularly preferably equal to or more than 20 μm and equal to or less than 40 μm. In such a case, the thermally conductive sheet 140 having superior balance between thermal conductivity and electrical insulating properties can be realized.

In addition, the lower limit of the average void diameter of the voids 146 in the secondary agglomerated particles 144 is not particularly limited; however, from the viewpoint of improving the property of the secondary agglomerated particle 144 of being impregnated with the thermosetting resin 145, the lower limit is preferably equal to or larger than 2 μm, more preferably equal to or larger than 10 μm, still more equal to or larger than preferably 15 μm, and particularly preferably equal to or larger than 20 μm. The upper limit of the average void diameter of the voids 146 in the secondary agglomerated particles 144 is not particularly limited; however, from the viewpoint of enhancing the thermal conductivity of the secondary agglomerated particles 144, the upper limit is preferably equal to or smaller than 150 μm, more preferably equal to or smaller than 100 μm, still more preferably equal to or smaller than 50 μm, and particularly preferably equal to or smaller than 40 μm.

Meanwhile, the average void diameter of the voids 146 can be measured using an electron micrograph. For example, the average void diameter is measured in the following order. First, the thermally conductive sheet 140 is cut using a microtome or the like so as to produce a section. Next, several photographs of the section of the thermally conductive sheet 140, which are magnified several thousand times, are taken using a scanning electron microscope. Next, arbitrary secondary agglomerated particles 144 are selected, and the void diameters d₁ thereof are measured from the photographs. At this time, ten or more void diameters d₁ are measured, and the average value thereof is considered as the average void diameter.

The average pore diameter of the communicating pores 148 in the secondary agglomerated particles 144 is not particularly limited, but is preferably equal to or more than 1 μm and equal to or less than 50 μm, more preferably equal to or more than 2 μm and equal to or less than 20 μm, still more preferably equal to or more than 3 μm and equal to or less than 15 μm, and particularly preferably equal to or more than 3 μm and equal to or less than 8 μm. In such a case, the thermally conductive sheet 140 having superior balance between thermal conductivity and electrical insulating properties can be realized.

In addition, the lower limit of the average pore diameter of the communicating pores 148 in the secondary agglomerated particles 144 is not particularly limited; however, from the viewpoint of improving the property of the secondary agglomerated particle 144 of being impregnated with the thermosetting resin 145, the lower limit is preferably equal to or larger than 1 μm, more preferably equal to or larger than 2 μm, and still more preferably equal to or larger than 3 μm. The upper limit of the average pore diameter of the communicating pores 148 in the secondary agglomerated particles 144 is not particularly limited; however, from the viewpoint of increasing the contact area between the secondary agglomerated particles 144 and improving the thermal conductivity of the thermally conductive sheet 140, the upper limit is preferably equal to or smaller than 50 μm, more preferably equal to or smaller than 20 μm, still more preferably equal to or smaller than 15 μm, far still more preferably equal to or smaller than 10 μm, and particularly preferably equal to or smaller than 8 μm.

Meanwhile, the average pore diameter of the communicating pores 148 can be measured using an electron micrograph. For example, the average pore diameter is measured in the following order. First, the thermally conductive sheet 140 is cut using a microtome or the like so as to produce a section. Next, several photographs of the section of the thermally conductive sheet 140, which are magnified several thousand times, are taken using a scanning electron microscope. Next, arbitrary secondary agglomerated particles 144 are selected, and the pore diameters d₂ thereof are measured from the photographs. At this time, the pore diameters d₂ of ten or more communicating pores are measured, and the average value thereof is considered as the average pore diameter.

The ratio of the average pore diameter of the communicating pores 148 to the average void diameter of the voids 146 is equal to or more than 0.05 and equal to or less than 1.0, preferably equal to or more than 0.10 and equal to or less than 0.50, more preferably equal to or more than 0.15 and equal to or less than 0.40, and particularly preferably equal to or more than 0.15 and equal to or less than 0.30. In such a case, the thermally conductive sheet 140 having superior balance between thermal conductivity and electrical insulating properties can be realized.

In addition, the lower limit of the ratio of the average pore diameter of the communicating pores 148 to the average void diameter of the voids 146 is 0.05 or higher, preferably 0.08 or higher, more preferably 0.10 or higher, still more preferably 0.12 or higher, and particularly preferably 0.15 or higher, from the viewpoint of improving the property of the secondary agglomerated particle 144 of being impregnated with the thermosetting resin 145.

In addition, the upper limit of the ratio of the average pore diameter of the communicating pores 148 to the average void diameter of the voids 146 is 1.0 or lower, preferably 0.80 or lower, more preferably 0.50 or lower, still more preferably 0.40 or lower, far still more preferably 0.35 or lower, and particularly preferably 0.30 or lower, from the viewpoint of increasing the contact area between the secondary agglomerated particles 144 and improving the thermal conductivity of the thermally conductive sheet 140.

The average major diameter of the primary particles of scaly boron nitride constituting the secondary agglomerated particles 144 is preferably equal to or more than 0.01 rpm and equal to or less than 15 μm and more preferably equal to or more than 0.1 μm and equal to or less than 12 μm. In such a case, the thermally conductive sheet 140 having superior balance between thermal conductivity and electrical insulating properties can be realized.

Meanwhile, this average major diameter can be measured using an electron micrograph. For example, the average major diameter is measured in the following order. First, the secondary agglomerated particle 144 is cut using a microtome or the like so as to produce a section. Next, several photographs of the section of the thermally conductive sheet 140, which are magnified several thousand times, are taken using a scanning electron microscope. Next, arbitrary secondary agglomerated particles 144 are selected, and the major diameters of the primary particles of scaly boron nitride are measured from the photographs. At this time, the major diameters of 1000 or more primary particles are measured, and the average value thereof is considered as the average major diameter.

The secondary agglomerated particle 144 can be formed by, for example, injecting scaly boron nitride powder and melamine borate into an aqueous solution in which a water-soluble binder is dissolved, mixing them together, agglomerating the obtained slurry using a well-known method such as a spray drying method, and then firing the slurry.

In order to form the void 146 and the communicating pore 148, the ratio between scaly boron nitride powder and melamine borate, the amount of the water-soluble binder injected into the slurry, and firing conditions are important.

The ratio between scaly boron nitride powder and melamine borate is, for example, in a range of 30:100 (mass ratio) to 1:100 (mass ratio) (scaly boron nitride powder:melamine borate).

The firing temperature is set to a high temperature, for example, 1500° C. to 2500° C. The firing time is, for example, in a range of 1 hour to 15 hours. The amount of the binder is set, for example, in a range of 1.5% by mass to 30% by mass with respect to 100% by mass of the slurry. In such a case, the secondary agglomerated particle 144 having the void 146 and the communicating pore 148 can be obtained.

The size of the void 146 in the secondary agglomerated particle 144 can be controlled by adjusting the concentration of solid contents in the slurry to be a desired value. When the concentration of solid contents in the slurry is decreased, it is possible to enlarge the void, and, when the concentration of solid contents in the slurry is increased, it is possible to contract the void.

In addition, the size of the communicating pore 148 in the secondary agglomerated particle 144 can be controlled using the amount of the water-soluble binder. When the amount of the water-soluble binder is increased, it is possible to enlarge the communicating pore 148, and, when the amount of the water-soluble binder is decreased, it is possible to contract the communicating pore 148.

As the water-soluble binder, a polyacrylate-based binder is preferably used.

In addition, the content of the secondary agglomerated particles 144 in the thermally conductive sheet 140 is, for example, preferably equal to or more than 50% by mass and equal to or less than 95% by mass and more preferably equal to or more than 65% by mass and equal to or less than 90% by mass. When the content of the secondary agglomerated particles 144 is set to the above-described lower limit value or higher, it is possible to more effectively improve the thermal conductivity or mechanical strength of the thermally conductive sheet 140. On the other hand, when the content of the secondary agglomerated particles 144 is set to the above-described upper limit value or lower, the film-forming property or workability of the resin composition is improved, and thus it is possible to further improve the uniformity of the film thickness of the thermally conductive sheet 140.

The filler (B) according to the present embodiment preferably further includes primary particles of scaly boron nitride different from the primary particles of the scaly boron nitride constituting the secondary agglomerated particles 144 from the viewpoint of further improving the thermal conductivity of the thermally conductive sheet 140. The average major diameter of the primary particles of scaly boron nitride different from the primary particles of the scaly boron nitride constituting the secondary agglomerated particles 144 is preferably equal to or more than 0.01 μm and equal to or less than 15 μm and more preferably equal to or more than 0.1 μm and equal to or less than 5 μm. In such a case, the thermally conductive sheet 140 having superior balance between thermal conductivity and electrical insulating properties can be realized.

From the viewpoint of achieving the balance between thermal conductivity and electrical insulating properties, the filler (B) may further include, for example, silica, alumina, boron nitride, aluminum nitride, silicon carbide, and the like as long as the effect of the present invention is not impaired. Only one substance of the above-described substances may be used, or two or more substances may be jointly used.

(Curing Agent (C))

In a case in which the epoxy resin (A1) is used as the thermosetting resin (A), the thermally conductive sheet 140 preferably further includes a curing agent (C).

As the curing agent (C), one or more curing agents selected from curing catalysts (C-1) and phenol-based curing agents (C-2) can be used.

Examples of the curing catalysts (C-1) include organic metal salts such as zinc naphthenate, cobalt naphthenate, tin octylate, cobalt octylate, bisacetylacetonato cobalt(II), and trisacetylacetonato cobalt(III); tertiary amines such as trimethylamine, tributylamine, and 1,4-diazabicyclo[2.2.2]octane; imidazoles such as 2-phenyl-4-methylimidazole, 2-ethyl-4-methylimidazole, 2,4-diethylimidazole, 2-phenyl-4-methyl-5-hydroxyimidazole, and 2-phenyl-4,5-dihydroxymethylimidazole; organic phosphorous compounds such as triphenylphosphine, tri-p-tolylphosphine, tetraphenylphosphonium tetraphenylborate, triphenylphosphine triphenylborane, and 1,2-bis-(diphenylphosphino)ethane; phenol compounds such as phenol, bisphenol A, and nonylphenol; organic acids such as acetic acid, benzoic acid, salicylic acid, and p-toluenesulfonic acid; and mixtures thereof. As the curing catalyst (C-1), only one curing catalyst of the above-described curing catalysts and derivatives thereof can be used, or two or more curing catalysts of the above-described curing catalysts and derivatives thereof can be used.

The content of the curing catalyst (C-1) in the thermally conductive sheet 140 is not particularly limited, but is preferably equal to or more than 0.001% by mass and equal to or less than 1% by mass with respect to 100% by mass of the thermally conductive sheet.

In addition, examples of the phenol-based curing agents (C-2) include novolac-type phenol resins such as a phenol novolac resin, a cresol novolac resin, a trisphenol methane-type phenol novolac resin, a naphthol novolac resin, and an aminotriazine novolac resin; modified phenol resins such as a terpene-modified phenol resin and a dicyclopentadiene-modified phenol resin; aralkyl-type resins such as a phenol aralkyl resin having a phenylene skeleton and/or a biphenylene skeleton and a naphthol aralkyl resin having a phenylene skeleton and/or a biphenylene skeleton; bisphenol compounds such as bisphenol A and bisphenol F; resol-type phenol resins; and the like, and only one phenol-based curing agent may be used, or two or more phenol-based curing agents may be jointly used.

Among these, from the viewpoint of improving the glass transition temperature and decreasing the linear expansion coefficient, the phenol-based curing agent (C-2) is preferably the novolac-type phenol resin or the resol-type phenol resin.

The content of the phenol-based curing agent (C-2) is not particularly limited, but is preferably equal to or more than 1% by mass and equal to or less than 30% by mass and more preferably equal to or more than 5% by mass and equal to or less than 15% by mass, with respect to 100% by mass of the thermally conductive sheet.

(Coupling Agent (D))

The thermally conductive sheet 140 may further include a coupling agent. The coupling agent (D) is capable of improving wettability in the interface between the thermosetting resin (A) and the filler (B).

As the coupling agent (D), any coupling agent that is ordinarily used can be used, and specifically, one or more coupling agents selected from an epoxy silane coupling agent, a cationic silane coupling agent, an aminosilane coupling agent, a titanate-based coupling agent, and a silicone oil-type coupling agent are preferably used.

The amount of the coupling agent (D) added is dependent on the specific surface area of the filler (B) and is thus not particularly limited, but the amount thereof is preferably equal to or more than 0.05 parts by mass and equal to or less than 3 parts by mass and particularly preferably equal to or more than 0.1 parts by mass and equal to or less than 2 parts by mass, with respect to 100 parts by mass of the filler (B).

(Phenoxy Resin (E))

Furthermore, the thermally conductive sheet 140 may further include a phenoxy resin (E). The inclusion of the phenoxy resin (E) is capable of further improving the flex resistance of the thermally conductive sheet 140.

In addition, when the thermally conductive sheet includes the phenoxy resin (E), it becomes possible to decrease the modulus of elasticity of the thermally conductive sheet 140, and it is possible to improve the stress relaxation force of the thermally conductive sheet 140.

Furthermore, when the thermally conductive sheet includes the phenoxy resin (E), an increase in the viscosity reduces the fluidity, and the generation of voids and the like can be suppressed. In addition, adhesiveness between the thermally conductive sheet 140 and the thermal radiation member can be improved. With these synergetic effects, the insulating reliability of the semiconductor device can be further enhanced.

Examples of the phenoxy resin (E) include a phenoxy resin having a bisphenol skeleton, a phenoxy resin having a naphthalene skeleton, a phenoxy resin having an anthracene skeleton, a phenoxy resin having a biphenyl skeleton, and the like. In addition, it is also possible to use a phenoxy resin having a structure including a plurality of these skeletons.

The content of the phenoxy resin (E) is, for example, equal to or more than 3% by mass and equal to or less than 10% by mass with respect to 100% by mass of the thermally conductive sheet.

(Other Components)

The thermally conductive sheet 140 is allowed to include an antioxidant, a levelling agent, and the like as long as the effect of the present invention is not impaired.

The thermally conductive sheet 140 according to the present embodiment can be produced, for example, as described below.

First, the respective components described above are added to a solvent, thereby obtaining a varnish-form resin composition for the thermally conductive sheet. In the present embodiment, the resin composition for the thermally conductive sheet can be obtained by, for example, adding the thermosetting resin (A) and the like to a solvent so as to produce a resin varnish, then, adding the filler (B) to the resin varnish, and kneading the components using three rollers or the like. In such a case, the filler (B) can be more uniformly dispersed in the thermosetting resin (A).

The solvent is not particularly limited, and examples thereof include methyl ethyl ketone, methyl isobutyl ketone, propylene glycol monomethyl ether, cyclohexanone, and the like.

Next, the resin composition for the thermally conductive sheet is shaped into a sheet shape, thereby forming a thermally conductive sheet. In the present embodiment, a base material-attached resin layer can be obtained by, for example, applying the varnish-form resin composition for the thermally conductive sheet onto a base material and then drying the resin composition through a thermal treatment. Examples of the base material include metal foils constituting the thermal radiation member, a lead frame, a peelable carrier material, or the like. In addition, the thermal treatment for drying the resin composition for the thermally conductive sheet is carried out under conditions of, for example, 80° C. to 150° C. and 5 minutes to 1 hour. The film thickness of the resin layer is, for example, equal to or more than 50 μm and equal to or less than 500 μm.

In addition, when the base material is removed from the base material-attached resin layer, the thermally conductive sheet 140 can be obtained.

Next, it is preferable that the base material-attached resin layer is compressed by passing through between two rollers to remove air bubbles in the resin layer.

In the present embodiment, the degree of thermal conductivity of the thermally conductive sheet 140 can be improved by including a step of removing air bubbles by applying a compressive pressure to the base material-attached resin layer using the rollers. This is presumed to be because the removal of air bubbles increases the density of the resin components in the thermally conductive sheet 140, and the transformation of the secondary agglomerated particles in the filler (B) caused by the compressive pressure enhances the adhesiveness of the filler (B) to the thermosetting resin (A).

Next, a semiconductor device according to the present embodiment will be described. FIG. 3 is a sectional view of the semiconductor device 100 according to an embodiment of the present invention.

Hereinafter, in order to simplify description, in some cases, it is assumed that the positional relationship (vertical structure relationship or the like) between individual components in the semiconductor device 100 coincides with the relationships illustrated in the drawings. However, the positional relationship in the description has no relationship with the positional relationship while the semiconductor device 100 is used or manufactured.

In the present embodiment, an example in which a metal plate is used as a heat sink will be described. The semiconductor device 100 according to the present embodiment includes a heat sink 130, a semiconductor chip 110 provided on a first face 131 side of the heat sink 130, the thermally conductive material 140 joined to a second face 132 on a side of the heat sink 130 opposite to the first face 131, and an encapsulating resin 180 for encapsulating the semiconductor chip 110 and the heat sink 130.

Hereinafter, the semiconductor device will be described in detail.

The semiconductor device 100 includes, for example, in addition to the above-described constitution, a conductive layer 120, a metal layer 150, leads 160, and a wire (metal wire) 170.

An electrode pattern, not illustrated, is formed on an upper surface 111 of the semiconductor chip 110, and a conductive pattern, not illustrated, is formed on a lower surface 112 of the semiconductor chip 110. The lower surface 112 of the semiconductor chip 110 is fixed to the first face 131 of the heat sink 130 through the conductive layer 120 such as silver paste. The electrode pattern on the upper surface 111 of the semiconductor chip 110 is electrically connected to an electrode 161 of the lead 160 through the wire 170.

The heat sink 130 is constituted with a metal.

The encapsulating resin 180 encapsulates, in addition to the semiconductor chip 110 and the heat sink 130, the wire 170, the conductive layer 120, and a part of each of the leads 160 inside. The other part of each of the leads 160 protrudes outside the encapsulating resin 180 from the side surface of the encapsulating resin 180. In the case of the present embodiment, for example, a lower surface 182 of the encapsulating resin 180 and the second face 132 of the heat sink 130 are positioned on the same plane.

An upper surface 141 of the thermally conductive material 140 is attached to the second face 132 of the heat sink 130 and the lower surface 182 of the encapsulating resin 180. That is, the encapsulating resin 180 is in contact with a surface on the heat sink 130 side (the upper surface 141) of the thermally conductive material 140 around the heat sink 130.

A lower surface 142 of the thermally conductive material 140 is fixed to an upper surface 151 of the metal layer 150. That is, one surface (the upper surface 151) of the metal layer 150 is fixed to a surface (the lower surface 142) opposite to the heat sink 130 side of the thermally conductive material 140.

In the planar view, the outline of the upper surface 151 of the metal layer 150 and the outline of the surface (the lower surface 142) opposite to the heat sink 130 side of the thermally conductive material 140 preferably overlap each other.

In addition, the entire surface (the lower surface 152) of the metal layer 150 opposite to one surface (the upper surface 151) thereof is exposed from the encapsulating resin 180. Meanwhile, in the case of the present embodiment, since the thermally conductive material 140 is attached to the second face 132 of the heat sink 130 and the lower surface 182 of the encapsulating resin 180 on the upper surface 141 of the thermally conductive material as described above, the thermally conductive material 140 is exposed to outside of the encapsulating resin 180 except for the upper surface 141 thereof. In addition, the metal layer 150 is entirely exposed to the outside of the encapsulating resin 180.

Meanwhile, the second face 132 and the first face 131 of the heat sink 130 are respectively formed to be, for example, flat.

The actual mounting area of the semiconductor device 100 is not particularly limited and can be set, for example, equal to or more than 10 mm×10 mm and equal to or less than 100 mm×100 mm. Here, the actual mounting area of the semiconductor device 100 refers to the area of the lower surface 152 of the metal layer 150.

In addition, the number of the semiconductor chips 110 mounted on one heat sink 130 is not particularly limited. The number thereof may be one or more. For example, three or more (six or the like) semiconductor chips may be provided. That is, as an example, three or more semiconductor chips 110 may be provided on the first face 131 side of one heat sink 130 and the encapsulating resin 180 may collectively encapsulate these three or more semiconductor chips 110.

The semiconductor device 100 is, for example, a power semiconductor device. The semiconductor device 100 may have a 2 in 1 constitution in which two semiconductor chips 110 are encapsulated in the encapsulating resin 180, a 6 in 1 constitution in which six semiconductor chips 110 are encapsulated in the encapsulating resin 180, or a 7 in 1 constitution in which seven semiconductor chips 110 are encapsulated in the encapsulating resin 180.

Next, an example of a method for manufacturing the semiconductor device 100 according to the present embodiment will be described.

First, the heat sink 130 and the semiconductor chip 110 are prepared, and the lower surface 112 of the semiconductor chip 110 is fixed to the first face 131 of the heat sink 130 through the conductive layer 120 such as silver paste.

Next, a lead frame including the leads 160 (not illustrated) is prepared, and the electrode pattern on the upper surface 111 of the semiconductor chip 110 and the electrode 161 of the lead 160 are electrically connected to each other through the wire 170.

Next, the semiconductor chip 110, the conductive layer 120, the heat sink 130, the wire 170, and a part of each of the leads 160 are collectively encapsulated using the encapsulating resin 180.

Next, the thermally conductive material 140 is prepared, and the upper surface 141 of the thermally conductive material 140 is attached to the second face 132 of the heat sink 130 and the lower surface 182 of the encapsulating resin 180. Furthermore, one surface (the upper surface 151) of the metal layer 150 is fixed to the surface (the lower surface 142) opposite to the heat sink 130 side of the thermally conductive material 140. Meanwhile, before the thermally conductive material 140 is attached to the heat sink 130 and the encapsulating resin 180, the metal layer 150 may be fixed to the lower surface 142 of the thermally conductive material 140 in advance.

Next, the respective leads 160 are cut from the frame body (not illustrated) of the lead frame. As a result, the semiconductor device 100 having a structure as illustrated in FIG. 3 is obtained.

According to the above-described embodiment, the semiconductor device 100 includes the heat sink 130, the semiconductor chip 110 provided on the first face 131 side of the heat sink 130, the insulating thermally conductive material 140 attached to the second face 132 opposite to the first face 131 of the heat sink 130, and the encapsulating resin 180 encapsulating the semiconductor chip 110 and the heat sink 130.

As described above, while the deterioration of the insulating properties of the thermally conductive material does not appear as a problem in a case in which a package of a semiconductor device is smaller than a certain size, as the area of the package of the semiconductor device increases, the electric field becomes stronger at a place in the surface of the thermally conductive material at which the electric field is most concentrated. Therefore, it is considered that it is likely that deterioration of the insulating properties caused by a slight change in the film thickness of the thermally conductive material also appears as a problem.

In contrast, the semiconductor device 100 according to the present embodiment includes the thermally conductive material 140 with the above-described structure, and thus, even when the semiconductor device is, for example, a large-sized package having an actual mounting area in a range of equal to or more than 10 mm×10 mm and equal to or less than 100 mm×100 mm, it can be expected that sufficient durability is obtained.

In addition, even when the semiconductor device 100 according to the present embodiment has a structure in which, for example, three or more semiconductor chips 110 are provided on the first face 131 side of one heat sink 130 and the three or more semiconductor chips are collectively encapsulated with the encapsulating resin 180, that is, even when the semiconductor device 100 is a large-sized package, the semiconductor device includes the thermally conductive material 140 with the above-described structure, and thus it can be expected that sufficient durability is obtained.

In addition, in a case in which the semiconductor device 100 further includes the metal layer 150 of which one surface (the upper surface 151) is fixed to the surface (the lower surface 142) opposite to the heat sink 130 side of the thermally conductive material 140, it is possible to appropriately radiate heat using the metal layer 150, and thus the thermal radiation properties of the semiconductor device 100 are improved.

In addition, when the upper surface 151 of the metal layer 150 is smaller than the lower surface 142 of the thermally conductive material 140, the lower surface 142 of the thermally conductive material 140 is exposed to the outside, and there is a concern that the thermally conductive material 140 may crack due to a protruding object such as a foreign substance. On the other hand, when the upper surface 151 of the metal layer 150 is larger than the lower surface 142 of the thermally conductive material 140, the end portions of the metal layer 150 hang in the air, and thus it is likely that the metal layer 150 may peel off while being handled in a manufacturing step.

In contrast, in the planar view, when the semiconductor device is provided with a structure in which the outline of the upper surface 151 of the metal layer 150 and the outline of the lower surface 142 of the thermally conductive material 140 overlap each other, it is possible to suppress the generation of cracks in the thermally conductive material 140 and the peeling off of the metal layer 150.

In addition, since the entire surface of the lower surface 152 of the metal layer 150 is exposed from the encapsulating resin 180, it becomes possible to radiate heat on the entire surface of the lower surface 152 of the metal layer 150, and high thermal radiation properties of the semiconductor device 100 can be obtained.

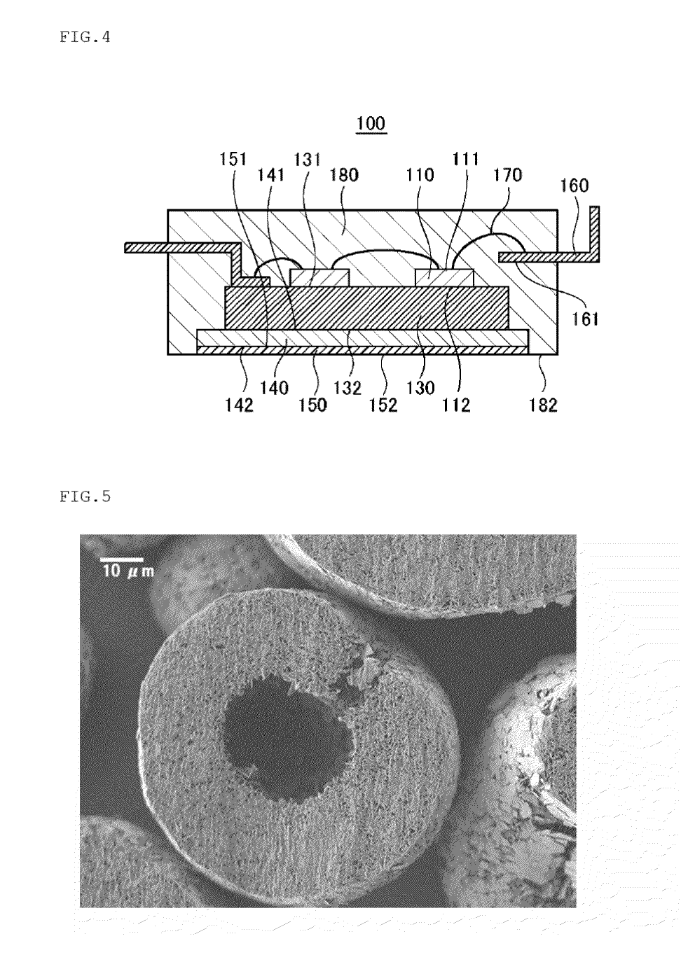

FIG. 4 is a sectional view of the semiconductor device 100 according to an embodiment of the present invention. This semiconductor device 100 is different from the semiconductor device 100 illustrated in FIG. 3 in terms of the following components described below, and components other than these are constituted in the same manner as in the semiconductor device 100 illustrated in FIG. 3.

In the case of the present embodiment, the thermally conductive material 140 is encapsulated in the encapsulating resin 180. In addition, the metal layer 150 is also encapsulated in the encapsulating resin 180 except for the lower surface 152 thereof. Furthermore, the lower surface 152 of the metal layer 150 and the lower surface 182 of the encapsulating resin 180 are positioned on the same plane.

Meanwhile, FIG. 4 illustrates an example in which at least two semiconductor chips 110 are mounted on the first face 131 of the heat sink 130. Electrode patterns on the upper surfaces 111 of these semiconductor chips 110 are electrically connected to each other through the wire. For example, a total of six semiconductor chips 110 are mounted on the first face 131. That is, for example, three sets of two semiconductor chips 110 are disposed in parallel in the depth direction in FIG. 4.

Meanwhile, when the semiconductor device 100 illustrated in FIG. 3 or 4 is mounted on a substrate (not illustrated), a power module including the substrate and the semiconductor device 100 can be obtained.

Meanwhile, the present invention is not limited to the above-described embodiments, and the embodiments may be modified, improved, or the like as long as the object of the present invention can be achieved.

### EXAMPLES

Hereinafter, the present invention will be described using examples and comparative examples, but the present invention is not limited thereto. Meanwhile, in the examples, “parts” indicate “parts by mass” unless particularly specified. In addition, individual thicknesses will be expressed using average film thicknesses.

(Production of Secondary Agglomerated Particles Constituted with Primary Particles of Scaly Boron Nitride)

A mixture obtained by mixing melamine borate (boric acid:melamine=2:1 (molar ratio)) and scaly boron nitride powder (average major diameter: 10 μm) (melamine borate:scaly boron nitride powder=10:1 (mass ratio)) was added to an aqueous solution of 3.0% by mass of ammonium polyacrylate, and the components were mixed together for 2 hours, thereby preparing a slurry for spray drying granulation (aqueous solution of ammonium polyacrylate:mixture=100:30 (mass ratio)). Next, the slurry was supplied to a spray granulator and was sprayed under conditions of a rotation speed of an atomizer of 15000 rpm, a temperature of 200° C., and a rate of supplying the slurry of 5 ml/min, thereby producing complex particles. Next, the obtained complex particles were fired in a nitrogen atmosphere under conditions of 2000° C. for 10 hours, thereby obtaining agglomerated boron nitride having an average particle diameter of 80 μm.

Here, the average particle diameter of the agglomerated boron nitride refers to the median diameter (D₅₀) obtained by measuring the volume-based particle size distribution of the particles using a laser diffraction particle size distribution analyzer (LA-500 manufactured by Horiba, Ltd.)

(Production of Thermally Conductive Sheet)

Thermally conductive sheets were produced as described below in Examples 1 to 5 and Comparative Examples 1 and 2.

First, a thermosetting resin and a curing agent were added to methyl ethyl ketone which was a solvent according to the mixture shown in Table 1 and were stirred together, thereby obtaining a solution of a thermosetting resin composition. Next, an inorganic filler was added to this solution, the components were preliminarily mixed together, and then were kneaded using three rollers, thereby obtaining a resin composition for the thermally conductive sheet in which the inorganic filler was uniformly dispersed. Next, the obtained resin composition for the thermally conductive sheet was aged under conditions of 60° C. for 15 hours. Next, the resin composition for the thermally conductive sheet was applied onto a copper foil using a doctor blade method, and then was dried through a thermal treatment at 100° C. for 30 minutes, thereby producing a resin sheet having a film thickness of 400 μm. Next, the resin sheet was compressed by passing through between two rollers so as to remove air bubbles in the resin sheet, thereby obtaining a B state-shape thermally conductive sheet having a film thickness of 300 μm.

Meanwhile, individual components in Table 1 will be described in detail below.

(Thermosetting Resin (A))

Epoxy resin 1: biphenylaralkyl-type epoxy resin (NC-3000, manufactured by Nippon Kayaku Co., Ltd.)

Epoxy resin 2: bisphenol A-type epoxy resin (828, manufactured by Mitsubishi Chemical Corporation)

Cyanate resin 1: phenol novolac-type cyanate resin (PT-30, manufactured by Lonza Japan Ltd.)

(Curing Catalyst C-1)

Curing catalyst 1: 2-phenyl-4,5-dihydroxymethylimidazole (2PHZ-PW, manufactured by Shikoku Chemicals Corporation)

Curing catalyst 2: triphenylphosphine (manufactured by Hokko Chemical Industry Co., Ltd.)

(Curing Agent C-2)

Phenol-based curing agent 1: trisphenol methane-type phenol novolac resin (MEH-7500, manufactured by Meiwa Plastic Industries, Ltd.)

(Filler (B))

Filler 1: agglomerated boron nitride produced by production of secondary agglomerated particles constituted with primary particles of scaly boron nitride.

Filler 2: agglomerated boron nitride having an average particle diameter of 80 μm which was produced using the same method as in the production example of the secondary agglomerated particles except for the fact that the concentration of the aqueous solution of ammonium polyacrylate was changed to 5% by mass in the production example.

Filler 3: agglomerated boron nitride having an average particle diameter of 80 μm which was produced using the same method as in the production example of the secondary agglomerated particles except for the fact that the concentration of the aqueous solution of ammonium polyacrylate was changed to 2% by mass in the production example.

Filler 4: agglomerated boron nitride having an average particle diameter of 80 μm which was produced using the same method as in the production example of the secondary agglomerated particles except for the fact that the concentration of the aqueous solution of ammonium polyacrylate was changed to 0.2% by mass in the production example.

Filler 5: agglomerated boron nitride having an average particle diameter of 80 μm which was produced using the same method as in the production example of the secondary agglomerated particles except for the fact that the concentration of the aqueous solution of ammonium polyacrylate was changed to 0.5% by mass in the production example.

(Observation of Voids 146 and Communicating Pores 148)

The voids 146 and the communicating pores 148 were observed using a scanning electron microscope.

Specifically, the voids and the communicating pores were observed in the following order. First, the thermally conductive sheet was cut using a microtome so as to produce a section. Next, a photograph of a section of the thermally conductive sheet, which was magnified several thousand times, was taken using a scanning electron microscope, and the voids 146 and the communicating pores 148 were observed.

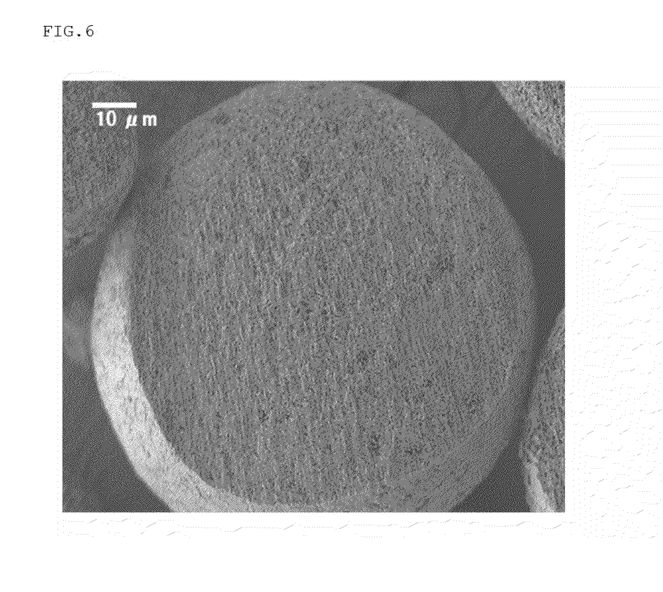

FIG. 5 illustrates an electron micrograph of Filler 1 used in Example 1. In addition, FIG. 6 illustrates an electron micrograph of Filler 4 used in Comparative Example 1.

(Measurement of Average Void Diameters of Voids 146 and Average Pore Diameter of Communicating Pores 148)

The average void diameters of the voids 146 and the average pore diameter of the communicating pores 148 were measured using an electron micrograph. First, the thermally conductive sheet was cut using a microtome so as to produce a section. Next, a few photographs of a section of the thermally conductive sheet, which was magnified several thousand times, were taken using a scanning electron microscope. Next, arbitrary secondary agglomerated particles 144 were selected, and the void diameters d₁ thereof and the pore diameters d₂ of the communicating pores were measured from the photographs. At this time, ten or more void diameters d₁ and pore diameters d₂ were measured, and the average values thereof were considered as the average void diameter and the average pore diameter.

(Insulating Reliability Evaluation)

For each of Examples 1 to 5 and Comparative Examples 1 and 2, the insulating reliability of the semiconductor package was evaluated as described below. First, a semiconductor package illustrated in FIG. 3 was produced using the thermally conductive sheet. Next, insulation resistance in continuous humidity was evaluated under conditions of a temperature of 85° C., a humidity of 85%, and an applied direct voltage of 1.5 kV using the semiconductor package. Meanwhile, resistance values of 10⁶Ω or lower were considered to be failure. The evaluation standards were as described below. The results are shown in Table 1.

AA: No failure occurred for equal to or more than 300 hours

A: Failure occurred for equal to or more than 200 hours and less than 300 hours

B: Failure occurred for equal to or more than 150 hours and less than 200 hours

C: Failure occurred for equal to or more than 100 hours and less than 150 hours

D: Failure occurred for less than 100 hours

(Heat Cycle Test) For each of Examples 1 to 5 and Comparative Examples 1 and 2, the heat cycle property of the semiconductor package was evaluated as described below. First, a semiconductor package illustrated in FIG. 3 was produced using the thermally conductive sheet. Next, a heat cycle test was carried out using three semiconductor packages. In the heat cycle test, one cycle was made up of five minutes at −40° C. and five minutes at +125° C., and 3000 cycles were carried out.

Next, whether or not there were any abnormalities in the semiconductor chip and the conductive layer was observed using an ultrasonic imaging device (FS300 manufactured by Hitachi Construction Machinery Japan Co., Ltd.). The results are shown in Table 1.

A: There were no abnormalities in the semiconductor chip and the conductive layer

B: Cracks were observed in a part of the semiconductor chip and/or the conductive layer, but there were no practical problems

C: Cracks were observed in a part of the semiconductor chip and/or the conductive layer, and there was a practical problem

D: Cracks were observed in both the semiconductor chip and the conductive layer, and the semiconductor package could not be used

TABLE 1

| | | | | | | | | | Com- | Com- |
|---|---|---|---|---|---|---|---|---|---|---|
| | | | | | | | | | parative | parative |
| | | | Unit | Example 1 | Example 2 | Example 3 | Example 4 | Example 5 | Example 1 | Example 2 |
| Resin | Thermosetting | Epoxy resin 1 | g | 19.0 | — | 11.4 | 19.0 | 19.0 | 19.0 | 19.0 |
| composition | resin | Epoxy resin 2 | g | — | 19.0 | — | — | — | — | — |
| | | Cyanate resin 1 | g | — | — | 7.6 | — | — | — | — |
| | Curing agent | Phenol-based | g | 7.1 | 7.1 | — | 7.1 | 7.1 | 7.1 | 7.1 |
| | | curing agent 1 | | | | | | | | |
| | | Curing | g | 0.1 | 0.1 | — | 0.1 | 0.1 | 0.1 | 0.1 |
| | | catalyst 1 | | | | | | | | |
| | | Curing | g | — | — | 0.1 | — | — | — | — |
| | | catalyst 2 | | | | | | | | |
| | Filler | Filler 1 | g | 73.8 | 73.8 | 73.8 | — | — | — | — |
| | | Filler 2 | g | — | — | — | 73.8 | — | — | — |
| | | Filler 3 | g | — | — | — | — | 73.8 | — | — |
| | | Filler 4 | g | — | — | — | — | — | 73.8 | — |
| | | Filler 5 | g | — | — | — | — | — | — | 73.8 |

| | | | | | | | | |
|---|---|---|---|---|---|---|---|---|
| Presence or absence of void in central | — | Present | Present | Present | Present | Present | Absent | Present |
| portion | | | | | | | | |
| Average void diameter of voids | μm | 30.0 | 30.0 | 30.0 | 30.0 | 30.0 | — | 30.0 |
| Presence or absence of communicating pores | — | Present | Present | Present | Present | Present | Absent | Absent |
| Average pore diameter of communicating pores | μm | 5.0 | 5.0 | 5.0 | 10.0 | 2.0 | — | — |
| Ratio of average pore diameter of | — | 0.17 | 0.17 | 0.17 | 0.33 | 0.07 | — | — |
| communicating pores to average void diameter | | | | | | | | |
| of voids | | | | | | | | |
| Insulating reliability evaluation | — | AA | AA | AA | A | B | D | C |
| Heat cycle test | — | A | A | A | B | B | D | C |

In the semiconductor packages of Examples 1 to 5 for which the thermally conductive sheet including Fillers 1 to 3 including the secondary agglomerated particles, in which voids were formed in the central portions and communicating pores beginning from the voids and communicating with the outer surfaces of the secondary agglomerated particles were formed, was used, the insulating reliability and the heat cycle property were excellent.

On the other hand, in the semiconductor package, of Comparative Example 2 for which the thermally conductive sheet including Filler 5 including the secondary agglomerated particles, in which no communicating pores were formed, was used, the insulating reliability and the heat cycle property were poor. Furthermore, in the semiconductor package of Comparative Example 1 for which the thermally conductive sheet Including Filler 4 including the secondary agglomerated particles, in which neither voids nor communicating pores were formed, was used, the insulating reliability and the heat, cycle property were poorer.

Therefore, it was found that, when the thermally conductive sheet according to the present invention is used, a highly durable semiconductor device can be obtained.

It is apparent that the present invention is not limited to the above embodiment, and may be modified and changed without departing from the scope and spirit of the invention.

What is claimed is:

1. A resin composition for a thermally conductive sheet comprising:
a thermosetting resin; and
a filler dispersed in the thermosetting resin,
wherein the filler includes secondary agglomerated particles satisfying the following conditions (a), (b), and (c):
(a) a void is formed in a central portion,
(b) a communicating pore which begins from the void and communicates with an outer surface of the secondary agglomerated particle is formed, and
(c) a ratio of an average pore diameter of the communicating pores to an average void diameter of the voids is equal to or more than 0.05 and equal to or less than 1.0.

2. The resin composition for a thermally conductive sheet according to claim 1,
wherein the secondary agglomerated particles are constituted with primary particles of scaly boron nitride.

3. The resin composition for a thermally conductive sheet according to claim 2,
wherein an average particle diameter of the secondary agglomerated particles is equal to or more than 5 μm and equal to or less than 200 μm.

4. The resin composition for a thermally conductive sheet according to claim 2,
wherein the filler further includes primary particles of scaly boron nitride different from the primary particles of the scaly boron nitride constituting the secondary agglomerated particles.

5. The resin composition for a thermally conductive sheet according to claim 1,
wherein the communicating pore is linearly formed from the void formed in the central portion toward the outer surface of the secondary agglomerated particle.

6. The resin composition for a thermally conductive sheet according to claim 1,
wherein the average pore diameter of the communicating pores is equal to or more than 1 μm and equal to or less than 50 μm.

7. The resin composition for a thermally conductive sheet according to claim 1,
wherein the average void diameter of the voids is equal to or more than 2 μm and equal to or less than 150 μm.

8. The resin composition for a thermally conductive sheet according to claim 1,
wherein an average major diameter of the primary particles constituting the secondary agglomerated particles is equal to or more than 0.01 μm and equal to or less than 15 μm.

9. The resin composition for a thermally conductive sheet according to claim 1,
wherein the thermosetting resin includes an epoxy resin.

10. The resin composition for a thermally conductive sheet according to claim 1,
wherein a content of the secondary agglomerated particles is equal to or more than 50% by mass and equal to or less than 95% by mass with respect to 100% by mass of the total solid contents in the resin composition for a thermally conductive sheet.

11. The resin composition for a thermally conductive sheet according to claim 1,
wherein a content of the thermosetting resin is equal to or more than 1% by mass and equal to or less than 30% by mass with respect to 100% by mass of the total solid contents in the resin composition for a thermally conductive sheet.

12. The resin composition for a thermally conductive sheet according to claim 1, further comprising:
one or two or more curing agents selected from curing catalysts and phenol-based curing agents.

13. A base material-attached resin layer comprising:
a resin layer made of the resin composition for a thermally conductive sheet according to claim 1; and
a base material provided on at least one surface of the resin layer.

14. A thermally conductive sheet formed of the resin composition for a thermally conductive sheet according to claim 1.

15. A semiconductor device comprising:
a metal plate;
a semiconductor chip provided on a first face side of the metal plate;
a thermally conductive material joined to a second face of the metal plate opposite to the first face; and
an encapsulating resin which encapsulates the semiconductor chip and the metal plate,
wherein the thermally conductive material is formed of the thermally conductive sheet according to claim 14.
